(19) United States
(12) Patent Application Publication
(10) Pub. No.: US 2016/0343657 A1
(43) Pub. Date: Nov. 24, 2016

(54) SEMICONDUCTOR DEVICE AND METHOD FOR MANUFACTURING THE SAME

(71) Applicant: KABUSHIKI KAISHA TOSHIBA, Tokyo (JP)

(72) Inventors: Keiichi SAWA, Yokkaichi (JP); Masayuki TANAKA, Yokkaichi (JP)

(73) Assignee: KABUSHIKI KAISHA TOSHIBA

(21) Appl. No.: 14/827,512

(22) Filed: Aug. 17, 2015

Related U.S. Application Data
(60) Provisional application No. 62/165,389, filed on May 22, 2015.

(51) Int. Cl. H01L 23/522; H01L 23/532; H01L 21/768; H01L 27/115; H01L 21/28

(52) U.S. Cl. CPC H01L 23/5226; H01L 27/11568; H01L 27/11582; H01L 21/28282; H01L 21/76802; H01L 21/7682; H01L 21/76879; H01L 23/53257

(57) ABSTRACT

According to one embodiment, a semiconductor device includes a stacked body, a core film, and a stacked film. The stacked body includes a plurality of conductive layers stacked with an insulating layer between the conductive layers. The core film extends in the stacked body in a stacking direction of the stacked body, and includes a metal oxide film having a higher dielectric constant than a dielectric constant of silicon nitride. The stacked film includes a semiconductor film and charge storage film. The semiconductor film is provided between the conductive layers and the core film. The semiconductor film extends in the stacking direction. The charge storage film is provided between the conductive layers and the semiconductor film.

### CROSS-REFERENCE TO RELATED APPLICATION

This application is based upon and claims the benefit of priority from U.S. Provisional Patent Application 62/165,389, filed on May 22, 2015; the entire contents of which are incorporated herein by reference.

### FIELD

Embodiments described herein relate generally to a semiconductor device and a method for manufacturing a semiconductor device.

### BACKGROUND

A memory device having a three-dimensional structure has been proposed. The memory device includes a stacked body including a plurality of electrode layers stacked via an insulating layer. A block insulating film, a charge storage film, a tunnel insulating film, and a semiconductor film functioning as a channel are formed on a side surface of a hole formed in the stacked body.

At a data erasing operation in which the semiconductor film is charged to a relatively high potential and the electrode layer is charged to a relatively low potential, a back-tunneling electron from the electrode layer may reach the semiconductor film and affect channel characteristics.

### BRIEF DESCRIPTION OF THE DRAWINGS

FIG. 1 is a schematic perspective view of a semiconductor device of an embodiment;

FIG. 2 is a schematic cross-sectional view of the semiconductor device of the embodiment;

FIG. 3 is a partial enlarged cross-sectional view of FIG. 2.

FIGS. 4 to 12 are schematic cross-sectional views showing a method for manufacturing the semiconductor device of the embodiment;

FIG. 13 is a schematic cross-sectional view of a semiconductor device of the embodiment; and

FIGS. 14 to 15B are schematic energy band diagram of the semiconductor device of the embodiment at an erasing operation.

### DETAILED DESCRIPTION

According to one embodiment, a semiconductor device includes a stacked body, a core film, and a stacked film. The stacked body includes a plurality of conductive layers stacked with an insulating layer between the conductive layers. The core film extends in the stacked body in a stacking direction of the stacked body, and includes a metal oxide film having a higher dielectric constant than a dielectric constant of silicon nitride. The stacked film includes a semiconductor film and charge storage film. The semiconductor film is provided between the conductive layers and the core film. The semiconductor film extends in the stacking direction. The charge storage film is provided between the conductive layers and the semiconductor film.

Hereinafter, embodiments will be described with reference to the drawings. Incidentally, in the drawings, the same components are denoted by the same reference numerals.

A semiconductor device of the embodiment is a semiconductor memory device.

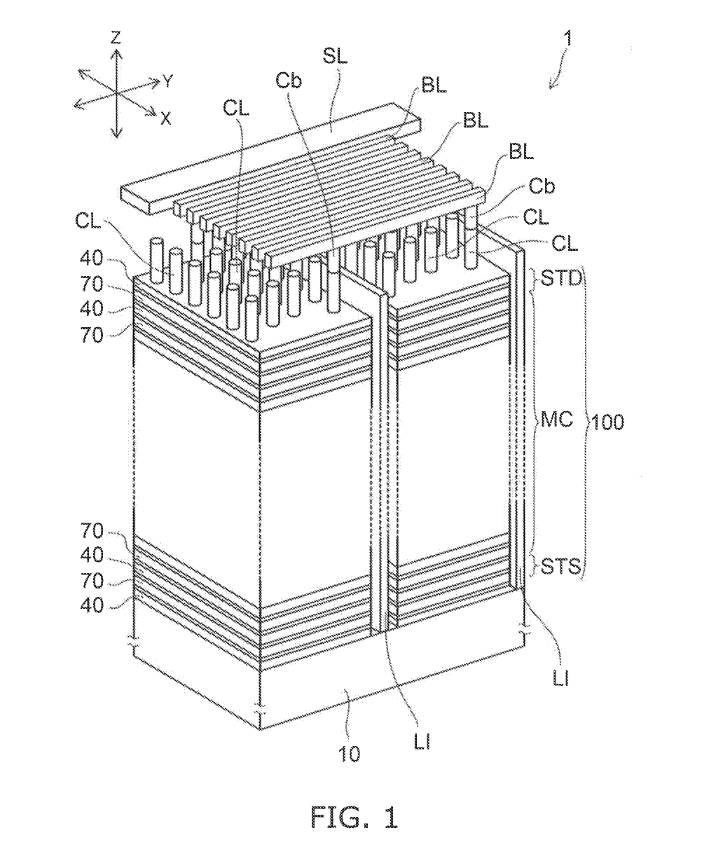

FIG. 1 is a schematic perspective view of a memory cell array 1 in a semiconductor memory device of the embodiment. In FIG. 1, two directions, which are parallel to the major surface of a substrate 10 and are orthogonal to each other, are defined as an X-direction (a first direction) and a Y-direction (a second direction). And a direction, which is orthogonal to these X-direction and Y-direction, is defined as a Z-direction (a third direction or a stacking direction).

The memory cell array 1 includes the substrate 10, a stacked body 100 provided on the major surface of the substrate 10, a plurality of columnar sections CL, a conductive member LI, and upper layer interconnections provided above the stacked body 100. In FIG. 1, bit lines BL and a source layer SL are shown as the upper layer interconnections.

The columnar section CL is formed in the shape of a circular column or an elliptical column extending in the stacking direction (Z-direction) in the stacked body 100. The conductive member LI extends in the stacking direction of the stacked body 100 (Z-direction) between the upper layer interconnections and the substrate 10, and also extends in the X-direction. The conductive member LI separates the stacked body 100 in the Y-direction.

The plurality of columnar sections CL is arranged, for example, in a staggered arrangement. Alternatively, the plurality of columnar sections CL may be arranged in a square grid pattern along the X-direction and Y-direction.

The bit lines (for example, metal films) BL are provided above the stacked body 100. The bit lines BL are spaced apart from each other in the X-direction, and each bit line BL extends in the Y-direction.

An upper end portion of the columnar section CL is connected to the bit line BL through a contact portion Cb. The plurality of columnar sections CL, each of which is selected from each of areas (blocks) separated in the Y-direction by the conductive member LI, are connected to one common bit line BL.

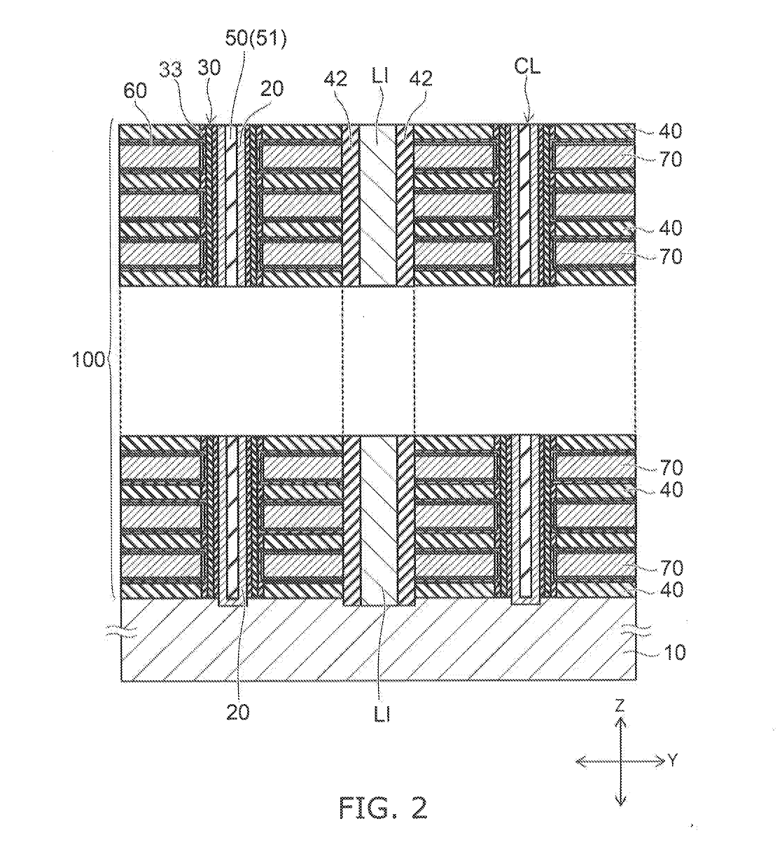

FIG. 2 is a schematic cross-sectional view of the stacked body 100, the columnar section CL, and the conductive member LI. FIG. 2 shows a cross section parallel to the Y-Z plane of FIG. 1.

The stacked body 100 includes a plurality of conductive layers 70 and a plurality of insulating layers 40 stacked on the major surface of the substrate 10. The conductive layers 70 are stacked in the Z-direction at a predetermined pitch via the Insulating layer 40.

The conductive layer 70 is a metal layer containing at least either of tungsten (W) and molybdenum (Mo). For example, the conductive layer 70 is a tungsten layer containing tungsten as a main component, or a molybdenum layer containing molybdenum as a main component. The insulating layer 40 contains, for example, silicon oxide (SiO₂) as a main component. An air gap as the insulating layer 40 may be formed between vertically adjacent conductive layers 70.

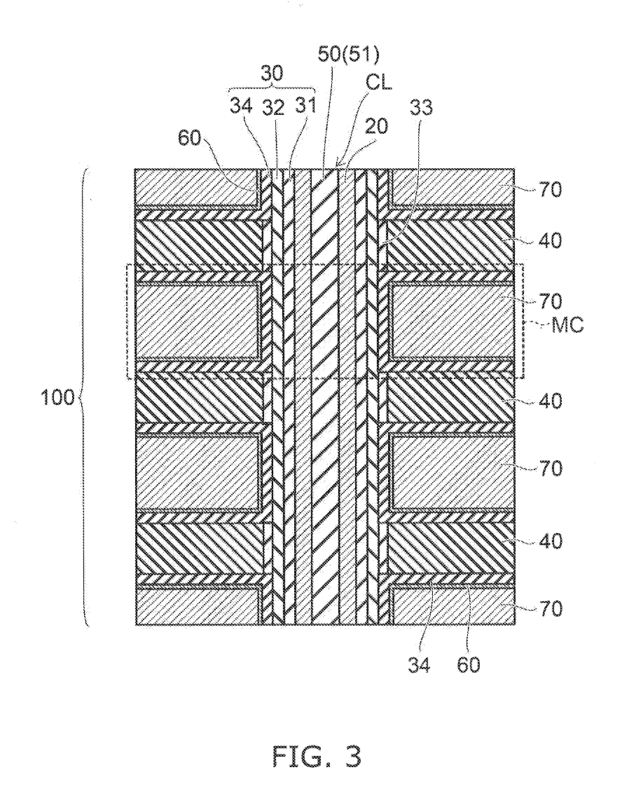

FIG. 3 is a partial enlarged cross-sectional view of FIG. 2.

The columnar section CL includes a memory film 30, a semiconductor film 20, and an insulating core film 50. The semiconductor film 20 extends in a pipe shape in the stacking direction (Z-direction) in the stacked body 100. The memory film 30 is provided between the conductive layer 70 and the semiconductor film 20, and surrounds the semiconductor film from the outer peripheral side.

The core film 50 is provided inside the semiconductor film 20 in a pipe shape. In the example shown in FIG. 3, as the core film 50, a single-layered metal oxide film 51 is provided in a pillar shape.

An upper end portion of the semiconductor film 20 is electrically connected to the bit line BL via the contact portion Cb shown in FIG. 1.

The memory film 30 includes a tunnel insulating film 31 as a first insulating film, a charge storage film 32, and a block insulating film 34 as a second insulating film. The charge storage film 32, the tunnel Insulating film 31, and the semiconductor film 20 continuously extend in the stacking direction of the stacked body 100. Between the conductive layer 70 and the semiconductor film 20, the block insulating film 34, the charge storage film 32, and the tunnel Insulating film 31 are provided in this order from the side of the conductive layer 70.

The tunnel insulating film 31 is in contact with the semiconductor film 20. The charge storage film 32 is provided between the block insulating film 34 and the tunnel insulating film 31.

The semiconductor film 20, the memory film 30, and the conductive layer 70 constitute a memory cell MC (FIG. 3). The memory cell MC has a vertical transistor structure in which the conductive layer 70 surrounds the periphery of the semiconductor film 20 via the memory film 30.

In the memory cell MC having the vertical transistor structure, the semiconductor film 20 functions as a channel, and the conductive layer 70 functions as a control gate (control electrode). The charge storage film 32 functions as a data storage layer that stores a charge injected from the semiconductor film 20.

The semiconductor memory device of the embodiment can electrically erase and write data freely, and is a nonvolatile semiconductor memory device that can hold memory contents even when the power is turned off.

The memory cell MC is, for example, a charge trap-type memory cell. The charge storage film 32 has a large number of trap sites where a charge is trapped in an insulating film, and includes, for example, a silicon nitride film.

The tunnel Insulating film 31 becomes an electric potential barrier when a charge is injected from the semiconductor film 20 into the charge storage film 32 or when a charge stored in the charge storage film 32 diffuses in the semiconductor film 20. The tunnel insulating film 31 includes, for example, a silicon oxide film.

The block insulating film 34 prevents a charge stored in the charge storage film 32 from diffusing in the conductive layer 70. The block insulating film 34 includes, for example, a silicon oxide film.

The block insulating film 34 is also provided between the conductive layer 70 and the insulating layer 40. The block insulating film 34 is in contact with the lower surface of the insulating layer 40 immediately above the conductive layer 70, and also in contact with the upper surface of the insulating layer 40 immediately below the conductive layer 70.

The block insulating film 34 between the conductive layer 70 and the charge storage film 32, and the block insulating film 34 between the conductive layer 70 and the insulating layer 40 are provided continuously and integrally.

Between the conductive layer 70 and the block insulating film 34, a nitride film 60 is provided. The nitride film 60 includes, for example, a titanium nitride film. The nitride film 60 enhances the adhesiveness between the conductive layer 70 and the block insulating film 34. Further, the nitride film 60 prevents a metal contained in the conductive layer 70 from diffusing toward the block insulating film 34. The nitride film 60 is in contact with the conductive layer 70 and the block insulating film 34. The nitride film 60 is provided continuously along the upper surface, the lower surface, and the side surface of the conductive layer 70.

Between the side surface of the insulating layer 40 and the charge storage film 32, the nitride film 60 and the block insulating film 34 are not provided. Between the side surface of the insulating layer 40 and the charge storage film 32, a cover insulating film 33 is provided. The cover insulating film 33 is, for example, a silicon oxide film.

As shown in FIG. 1, a drain-side select transistor STD is provided at an upper end portion of the columnar section CL, and a source-side select transistor STS is provided at a lower end portion of the columnar section CL. For example, the lowermost conductive layer 70 functions as a control gate (control electrode) of the source-side select transistor STS. For example, the uppermost conductive layer 70 functions as a control gate (control electrode) of the drain-side select transistor STD. The drain-side select transistor STD and the source-side select transistor STS are vertical transistors in which an electric current flows in the stacking direction of the stacked body 100 (Z-direction) similarly to the memory cell MC.

Between the drain-side select transistor STD and the source-side select transistor STS, a plurality of memory cells MC are provided. The memory cells MC, the drain-side select transistor STD, and the source-side select transistor STS are connected in series through the semiconductor film 20 to form one memory string. This memory string is, for example, arranged in a staggered arrangement in a plane direction parallel to the X-Y plane, and the memory cells MC are three-dimensionally provided in the X-direction, Y-direction, and Z-direction.

On both sidewalls in the Y-direction of the conductive member LI that separates the stacked body 100 in the Y-direction, as shown in FIG. 2, an insulating film 42 is provided. The insulating film 42 is provided between the stacked body 100 and the conductive member LI. In FIG. 1, the Illustration of the insulating film 42 is omitted.

The conductive member LI is, for example, a metal member containing tungsten as a main component. An upper end portion of the conductive member LI is connected to the source layer SL shown in FIG. 1 provided above the stacked body 100. The lower end of the conductive member LI is in contact with the substrate 10 as shown in FIG. 2. Further, the lower end of the semiconductor film 20 is in contact with the substrate 10. The substrate 10 is, for example, a silicon substrate doped with impurities and having conductivity. Therefore, the lower end of the semiconductor film 20 can be electrically connected to the source layer SL through the substrate 10 and the conductive member LI.

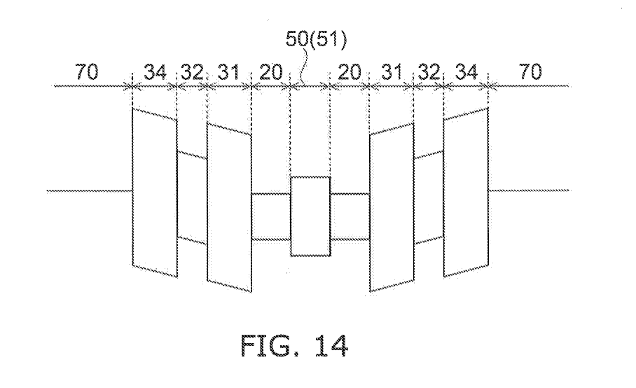

FIG. 14 is a schematic energy band diagram of the semiconductor memory device of the embodiment at an erasing operation.

At the erasing operation, the semiconductor film 20 is charged to a relatively high potential and the conductive layer 70 is charged to a relatively low potential, and due to a potential difference therebetween, holes are injected into the charge storage film 32 from the semiconductor film 20, and the electrons stored in the charge storage film 32 are eliminated.

Due to the potential difference between the semiconductor film 20 and the conductive layer 70 at that time, electrons in the conductive layer 70 tunnel back to the memory film 30, and further pass through the semiconductor film 20 and reach an Interface between the core film 50 and the semiconductor film 20 on the other side across the center axis of the columnar section CL (the center axis of the core film 50). Damage (defect) may be caused in the interface. This defect may cause a decrease in the mobility of a carrier in a channel formed in the semiconductor film 20.

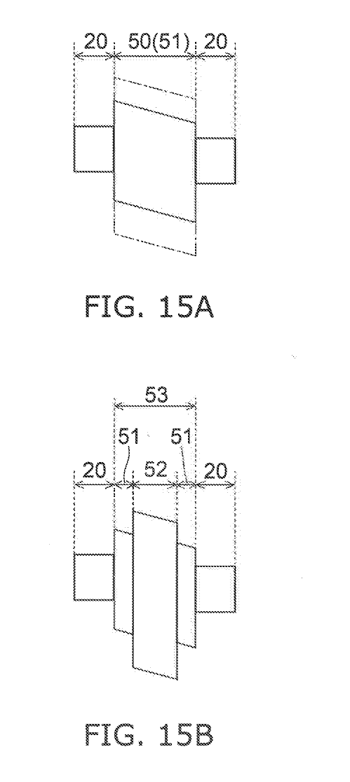

FIG. 15A is an energy band diagram of the semiconductor film 20 and the core film 50 of the semiconductor memory device of the embodiment at the erasing operation.

When the number of stacked layers in the stacked body 100 is increased to increase the thickness of the stacked body 100, the length of the semiconductor film 20 in the stacking direction is increased. It becomes difficult to control all parts of such a semiconductor film 20 to be charged to the same potential, and as shown in FIG. 15A, a potential difference may occur in two parts, which interpose the central axis of the core film 50, in the pipe-shaped semiconductor film 20 surrounding the core film 50. This potential difference, for example, accelerates back-tunneling electrons injected from the conductive layer 70 on the left side in FIG. 15A, passing through the semiconductor film 20 on the left side in FIG. 15A and the core film 50, and directed toward the interface between the semiconductor film 20 on the right side (the other side) in FIG. 15A and the core film 50. This acceleration of back-tunneling electrons increases the damage to the Interface between the semiconductor film 20 and the core film 50.

In FIG. 15A, an alternate long and short dash line indicates the energy band of a structure using a single-layered film of a silicon oxide film as the core film, and a solid line indicates the energy band of a structure using a single-layered film of the metal oxide film 51 as the core film 50 of the embodiment.

By using the metal oxide film 51 as the core film 50, an electric field at the interface between the semiconductor film 20 and the core film 50 is decreased as compared with the case of using the silicon oxide film. This decrease (relaxation) of the electric field decreases the energy of the back-tunneling electrons reaching the interface between the semiconductor film and the core film 50, and suppresses the damage to the interface by the electrons. As a result, the scattering of a carrier in a channel formed in the semiconductor film 20 at the defect is decreased, and the mobility can be improved.

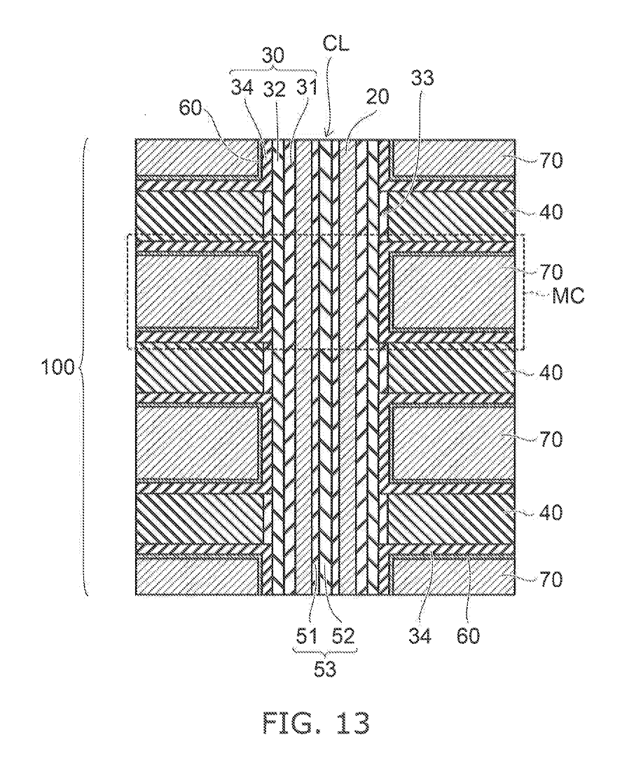

FIG. 13 is a cross-sectional view similar to FIG. 3 showing another configuration of the core film.

FIG. 15B is a schematic energy band diagram of the semiconductor memory device including the semiconductor film 20 and a core film 53 shown in FIG. 13 at the erasing operation.

In the example shown in FIG. 13, the core film 53 is a stacked film of a metal oxide film 51 and a silicon oxide film 52. In the inside of the semiconductor film 20, the pipe-shaped metal oxide film 51 is provided in contact with the semiconductor film 20, and the silicon oxide film 52 is provided in the inside of the metal oxide film 51.

Also in this example shown in FIG. 13, an electric field at an interface between the semiconductor film 20 and the core film 53 is decreased as compared with the case where the core film has a single-layered structure of a silicon oxide film, so that the damage to the interface by back-tunneling electrons can be suppressed. As a result, the scattering of a carrier at a defect in a channel in the semiconductor film 20 is decreased, and the mobility can be improved.

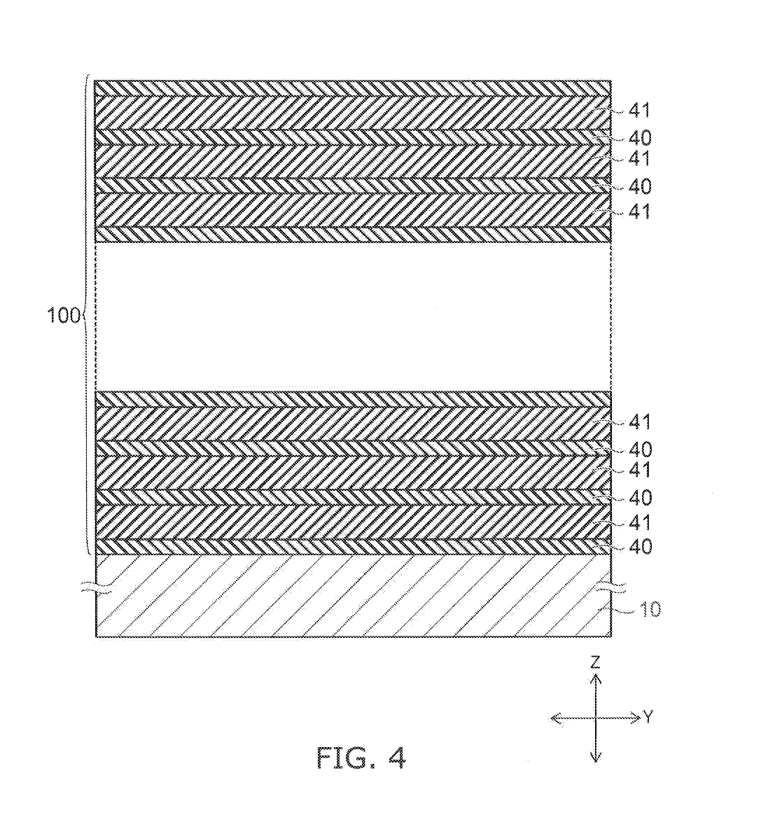

Next, with reference to FIGS. 4 to 12, a method for manufacturing the semiconductor memory device of the embodiment will be described.

As shown in FIG. 4, an insulating layer 40 as a first layer is formed on the major surface of a substrate 10, and a sacrifice layer 41 as a second layer composed of a different material from that of the insulating layer 40 is formed on the insulating layer 40. Thereafter, a process of alternately stacking the insulating layer 40 and the sacrifice layer 41 is repeated multiple times, whereby a stacked body 100 including a plurality of insulating layers 40 and a plurality of sacrifice layers 41 is formed on the substrate 10.

The substrate 10 is, for example, a single crystal silicon substrate.

As the insulating layer 40, for example, a silicon oxide film (SiO₂ film) is formed by a CVD (Chemical Vapor Deposition) method using TEOS (tetraethyl orthosilicate) gas. Alternatively, a silicon oxide film (SiO₂ film) as the insulating layer 40 may be formed by a plasma CVD method using SiH₄ gas and N₂O gas.

As the sacrifice layer 41, for example, a silicon nitride film (SiN film) is formed by a CVD method using SiH₂Cl₂ gas and NH₃ gas. Alternatively, a silicon nitride film (SiN film) as the sacrifice layer 41 may be formed by a plasma CVD method using SiH₂Cl₂ gas and NH₃ gas.

The sacrifice layer 41 is removed in a subsequent process, and a block insulating film 34, a nitride film 60, and a conductive layer 70 are formed in an air gap (space) formed by removing the sacrifice layer 41.

The sacrifice layer 41 may be any as long as it has a high etching selection ratio with respect to the insulating layer 40, and is not limited to a silicon nitride film. For example, a polycrystalline silicon film as the sacrifice layer 41 may be formed by a CVD method using SiH₄ gas.

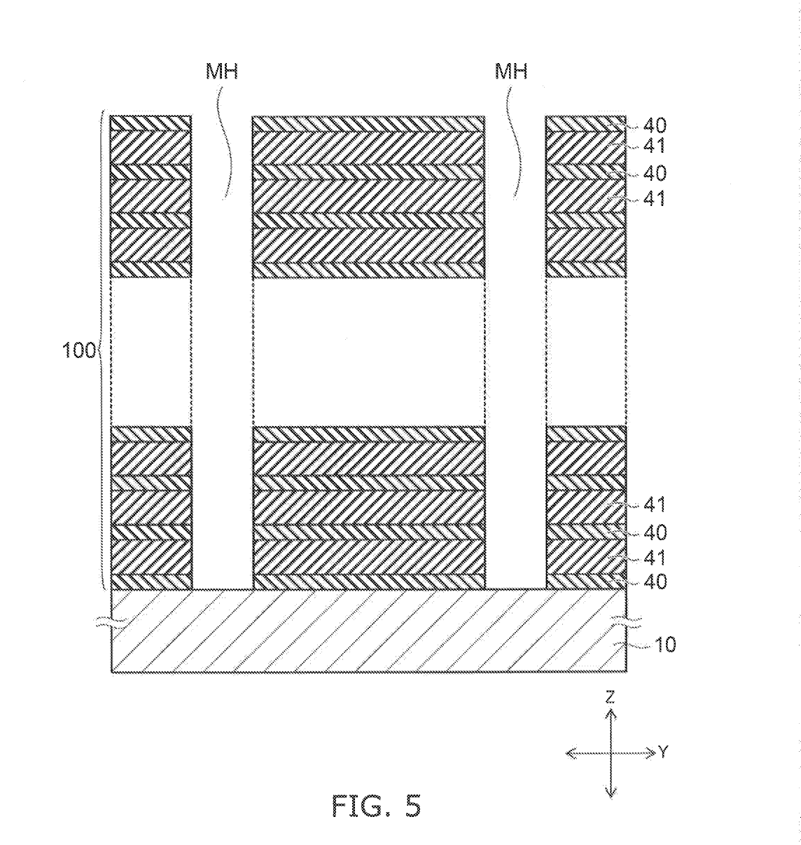

As shown in FIG. 5, a plurality of memory holes MH are formed in the stacked body 100. The memory holes MH are formed by, for example, an RIE (Reactive Ion Etching) method using a mask (not shown). The memory hole MH extends in the stacking direction of the stacked body 100 (Z-direction), and reaches the substrate 10 through the stacked body 100.

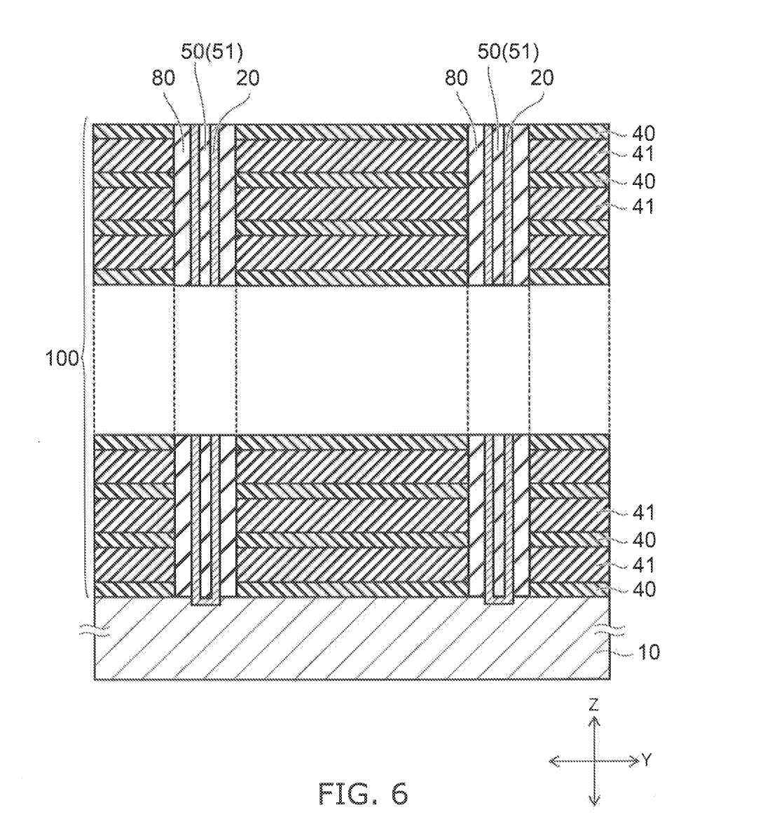

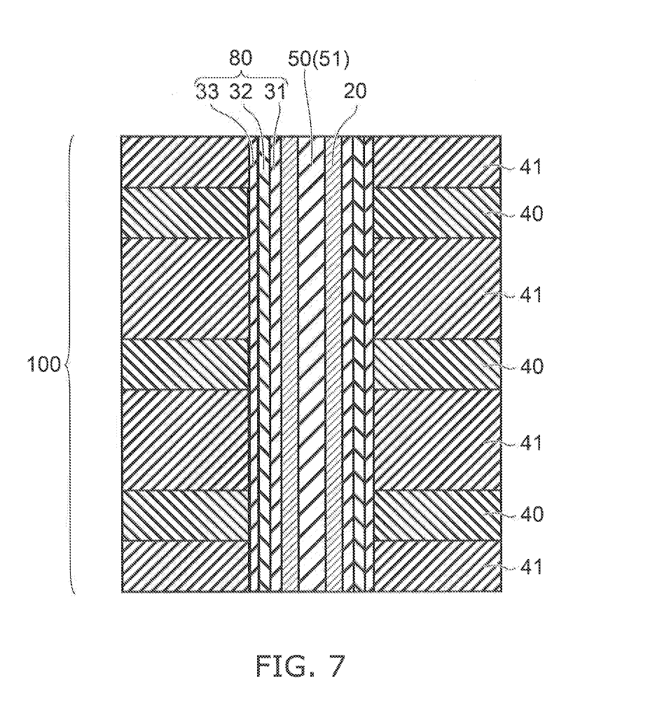

As shown in FIG. 6, and FIG. 7 which is a partial enlarged cross-sectional view of FIG. 6, a film 80, a semiconductor film 20, and a core film 50 are formed in the memory hole MH. The film 80 includes, as shown in FIG. 7, a cover insulating film 33, a charge storage film 32, and a tunnel insulating film 31.

First, for example, a silicon oxide film (SiO₂ film) as the cover insulating film 33 is formed on the side surface of the memory hole MH by an ALD (Atomic Layer Deposition) method. The cover Insulating film 33 is also formed on the bottom of the memory hole MH.

For example, a silicon nitride film (SiN film) as the charge storage film 32 is formed inside the cover insulating film 33 by an ALD method using SiH₂Cl₂ gas and NH₃ gas. As a source gas for silicon at this time, Si₂H₆ may be used in place of SiH₂Cl₂.

The charge storage film 32 may be any as long as it is a film capable of trapping a charge, and for example, a hafnium oxide film (HfOx film), an aluminum oxide film (AlOx film), or an aluminum nitride film (AlN film) may be used. Further, the charge storage film 32 may be a stacked film including at least two films selected from a silicon nitride film, a hafnium oxide film, an aluminum oxide film, and an aluminum nitride film.

For example, a silicon oxide film (SiO₂ film) as the tunnel Insulating film 31 is formed inside the charge storage film 32 by an ALD method using TDMAS (tris(dimethylamino)silane) gas and O₃ gas. Alternatively, a silicon oxide film (SiO₂ film) as the tunnel insulating film 31 may be formed by a CVD method using SiH₄ gas and N₂O gas.

A hollow is left inside the film 80 including the cover insulating film 33, the charge storage film 32, and the tunnel Insulating film 31. And a part of the film 80 deposited on the bottom of the memory hole MH on the lower side of the hollow is removed by, for example, an RIE method.

Thereafter, a semiconductor film 20 is formed on the side surface of the tunnel insulating film 31. The semiconductor film 20 is formed also on the bottom of the memory hole MH as shown in FIG. 6 and is in contact with the substrate 10. For example, a silicon film as the semiconductor film 20 is formed by a CVD method using SiH₄ gas. A silicon film as the semiconductor film 20 may be formed by a process for forming a seed layer using Si₂H₆ gas and a process for forming a main layer which is thicker than the seed layer using SiH₄ gas.

A hollow is left inside the semiconductor film 20, and a single-layered metal oxide film 51 is buried in the hollow as the core film 50. For example, an aluminum oxide film (AlOx film) as the metal oxide film 51 is formed by an ALD method using TMA (tetramethylaluminum) gas and O₃ gas.

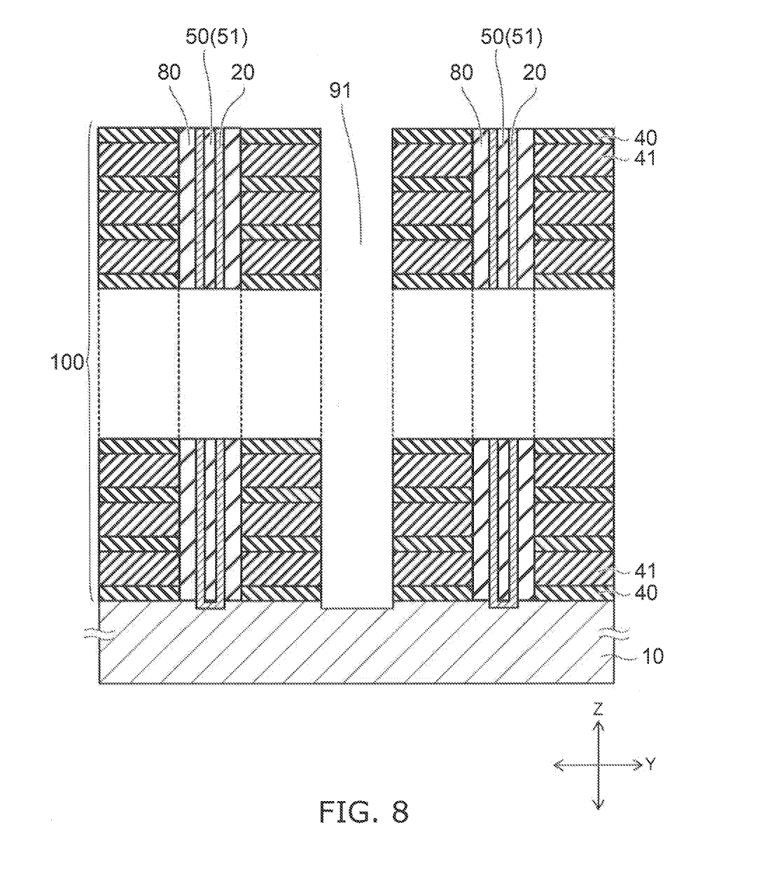

Subsequently, as shown in FIG. 8, a slit (or a trench) 91 is formed in the stacked body 100. The slit 91 is formed by, for example, an RIE method using a mask (not shown). The slit 91 extends in the stacking direction of the stacked body 100 (Z-direction), and reaches the substrate 10 through the stacked body 100. Further, the slit 91 extends in the depth direction of the drawing (X-direction) and separates the stacked body 100 in the Y-direction.

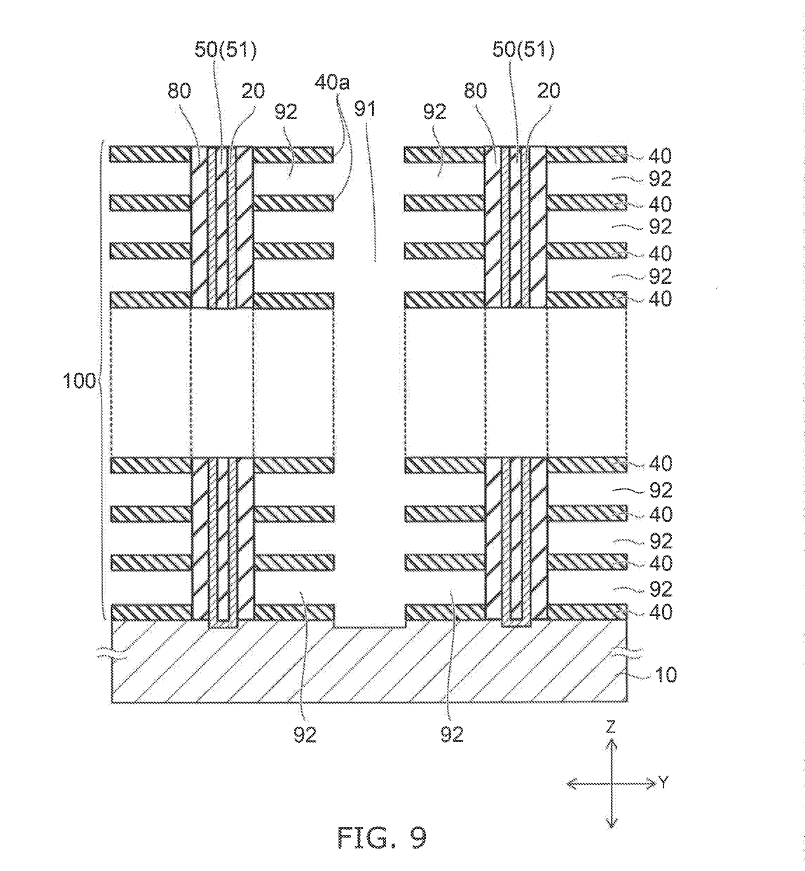

Subsequently, the sacrifice layer 41 is removed by, for example, wet etching using hot phosphoric acid to be supplied through the slit 91. By removing the sacrifice layer 41, as shown in FIG. 9, an air gap (or a space) 92 is formed between the insulating layers 40. The cover insulating film 33 protects the charge storage film 32 during this etching.

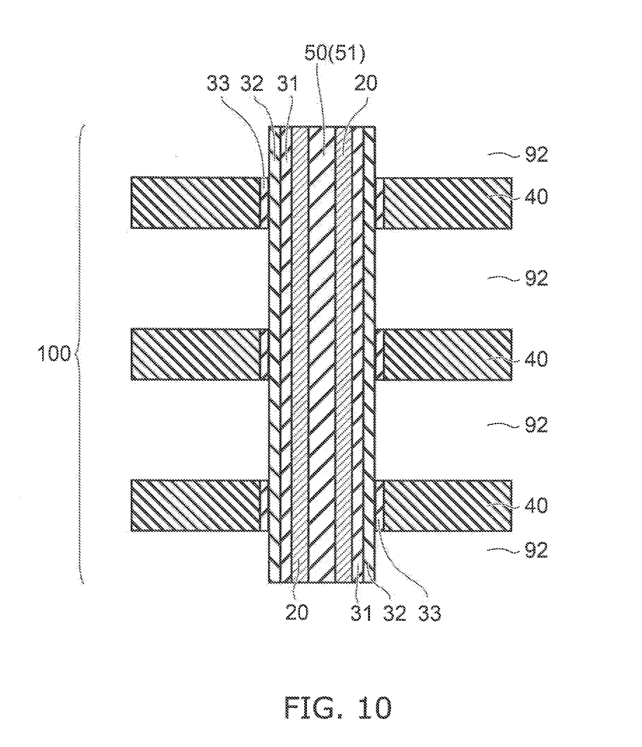

Further, the cover insulating film 33 is also partially removed by wet etching. The cover insulating film 33 facing the air gap 92 is removed as shown in the enlarged view of FIG. 10, and the charge storage film 32 is exposed in the air gap 92.

By controlling the etching rate at the removing of the cover insulating film 33 to be lower than the etching rate at the removing of the sacrifice layer 41, etching damage to the charge storage film 32 can be suppressed.

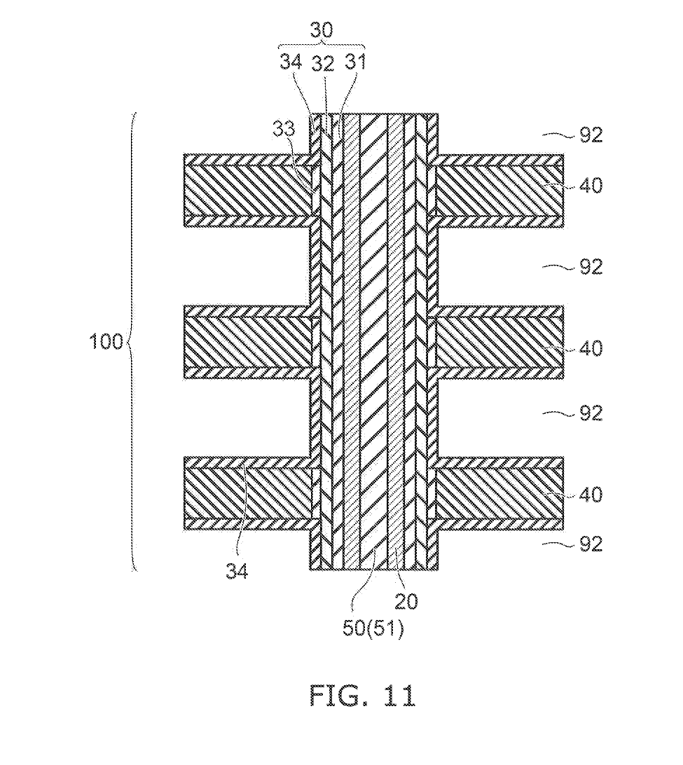

Subsequently, as shown in FIG. 11, the block Insulating film 34 is formed on the inner wall of the air gap 92. For example, a silicon oxide film (SiO₂ film) as the block Insulating film 34 is formed by an ALD method using TDMAS (tris(dimethylamino)silane) gas and O₃ gas. Alternatively, a silicon oxide film (SiO₂ film) as the block insulating film 34 may be formed by a CVD method using SiH₄ gas and N₂O gas.

The block insulating film 34 may be a stacked film of a silicon oxide film and a silicon nitride film. The block insulating film 34 may be a high-k film such as an aluminum oxide film (AlOx film), a hafnium oxide film (HfOx film), or a lanthanum aluminum oxide film (LaAlOx film). Further, the block insulating film 34 may be a stacked film of the above-mentioned high-k film and a silicon oxide film. Incidentally, the above-mentioned high-k film can be used also in the tunnel insulating film 31.

The block insulating film 34 is formed conformally along the upper and lower surfaces of the Insulating layer 40 and the charge storage film 32 exposed in the air gap 92.

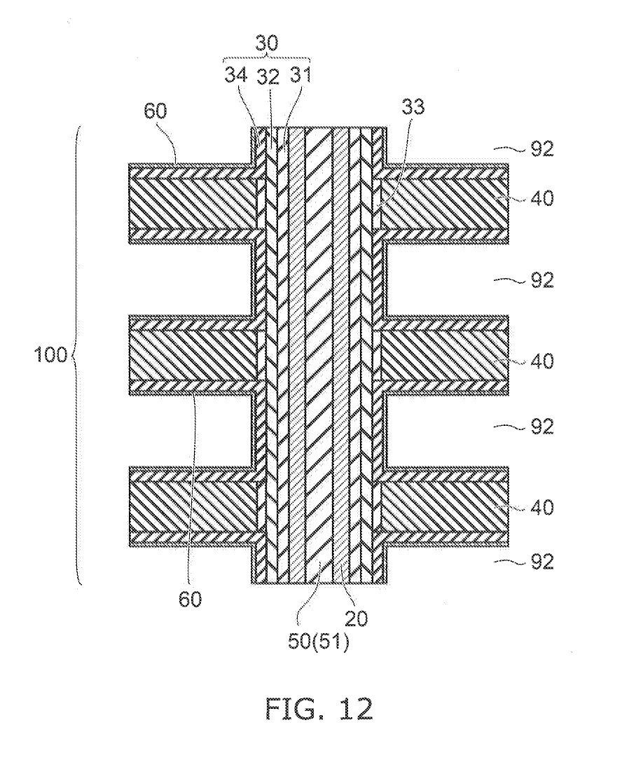

Subsequently, as shown in FIG. 12, for example, a titanium nitride film (TIN film) 60 is formed inside the block insulating film 34 by a CVD method using TiCl₄ gas and NH₃ gas. The titanium nitride film 60 is formed conformally along the block insulating film 34.

The air gap 92 is left inside the titanium nitride film 60. As shown in FIG. 3, the conductive layer 70 is formed in the air gap 92.

For example, a tungsten layer as the conductive layer 70 is buried in the air gap 92 by a CVD method using tungsten fluoride (WF₆) gas. Alternatively, for example, a molybdenum layer as the conductive layer 70 is buried in the air gap 92 by a CVD method using molybdenum fluoride (MoF₆) gas.

By interposing the titanium nitride film 60 between the block insulating film 34 and the conductive layer 70, the adhesiveness between the conductive layer 70 and the titanium nitride film 60 can be enhanced as compared with the case where the conductive layer 70 is directly formed on the block insulating film 34.

Further, the titanium nitride film 60 functions as a barrier layer for preventing a metal (tungsten or molybdenum) contained in the conductive layer 70 from diffusing toward the memory film 30.

Other than the titanium nitride film, for example, a nitride film such as a tantalum nitride film (TaN film), a tantalum aluminum nitride film (TaAlN film), or a titanium silicon nitride film (TiSiN film) may be interposed between the block insulating film 34 and the conductive layer 70.

A source gas for the conductive layer 70 flows into the air gap 92 through the slit 91 shown in FIG. 9. At this time, a material film (metal film) of the conductive layer 70 is deposited and formed also on a side surface 40a of the Insulating layer 40 exposed in the slit 91. Thereafter, the metal film on the side surface 40a of the insulating layer 40 is removed, and an electrical short circuit between different layers of the conductive layer 70 through the metal film is cut.

Further, the titanium nitride film 60 formed conformally along the inner wall of the air gap 92 before forming the conductive layer 70 is formed also on the side surface 40a of the insulating layer 40, and different layers of the titanium oxide film 60 are continuous through a portion formed on the side surface 40a of the insulating layer 40. The conductive layer 70 formed after forming the titanium nitride film 60 is in contact with the titanium nitride film 60, and therefore, through the titanium nitride film 60 having conductivity, a short circuit occurs between different layers of the conductive layer 70. Such titanium nitride film 60 formed on the side surface 40a of the insulating layer 40 is also removed, so that the connection in the vertical direction (stacking direction) of the titanium nitride film 60 is disconnected. An electrical short circuit between different layers of the conductive layer 70 through the titanium nitride film 60 is cut.

Thereafter, as shown in FIG. 2, a conductive member LI is formed in the slit 91 via an insulating film 42. The insulating film 42 is formed conformally on the side surface and the bottom of the slit 91. The insulating film 42 on the bottom of the slit 91 is removed by, for example, an RIE method, and the substrate 10 is exposed on the bottom of the slit 91. Thereafter, the conductive member LI is formed inside the insulating film 42 in the slit 91, and the lower end of the conductive member LI is in contact with the substrate 10. Further, thereafter, bit lines BL and a source layer SL shown in FIG. 1 are formed.

The metal oxide film 51 of the core film 50 of the embodiment may contain fluorine. For example, fluorine is absorbed in the metal oxide film 51 during deposition of the metal oxide film 51. Alternatively, fluorine is absorbed in the metal oxide film 51 after deposition of the metal oxide film 51. Alternatively, fluorine is absorbed in the metal oxide film 51 during and after deposition of the metal oxide film 51.

By introducing a gas containing fluorine (for example, ClF₃ gas) into a deposition chamber when the metal oxide film 51 is grown in a gas-phase, the metal oxide film 51 containing fluorine can be formed.

Alternatively, after forming the metal oxide film 51, fluorine can be absorbed in the metal oxide film 51 by exposing the metal oxide film 51 to a gas containing fluorine (for example, ClF₃ gas). The metal oxide film 51 has a property that it easily absorbs fluorine. Therefore, for example, by using a gas containing fluorine for cleaning the chamber, and set a wafer in the chamber containing the residual fluorine, fluorine can be absorbed in the metal oxide film 51.

Alternatively, after forming the metal oxide film 51, fluorine can be absorbed in the metal oxide film 51 while washing the rear surface or the bevel of the wafer with hydrofluoric acid. In particular, in the example shown in FIG. 13, after forming the metal oxide film 51, fluorine can be effectively absorbed in the metal oxide film 51.

A transistor of a control circuit (not shown) is formed on the surface of the substrate 10. After forming the stacked body 100 and the columnar sections CL, in order to activate an impurity diffusion layer (semiconductor region) functioning as a source and a drain of the transistor, annealing (a heat treatment) is performed at, for example, approximately 900 to 1000° C.

Further, in order to modify the respective films constituting the columnar section CL, annealing (a heat treatment) may be performed in, for example, a nitrogen gas atmosphere at approximately 700 to 1000° C.

During such a heat treatment, fluorine contained in the metal oxide film 51 diffuses. Fluorine contained in the metal oxide film 51 can diffuse into the stacked film including the semiconductor film 20, the tunnel Insulating film 31, the charge storage film 32, the block insulating film 34, and the titanium nitride film 60. Fluorine contained in the metal oxide film 51 can diffuse into the respective films in the above-mentioned stacked film, and also into interfaces between the respective films. Further, fluorine contained in the metal oxide film 51 can diffuse into an interface between the above-mentioned stacked film and the metal oxide film 51, and into an interface between the above-mentioned stacked film and the conductive layer 70.

The metal oxide film 51 is deposited in an amorphous state or a low crystalline state, and crystallized during the above-mentioned heat treatment. This crystallization promotes desorption and diffusion of fluorine from the metal oxide film 51.

Fluorine can be introduced into the memory film 30 and the semiconductor film 20 in the following way. Fluorine is introduced into the memory film 30 through the memory hole MH by an ion implantation method before forming the semiconductor film 20. Fluorine is introduced into the semiconductor film 20 through the memory hole MH by an ion implantation method before forming the core film 50. However, in such a case, a variation in the implantation amount of fluorine between an upper portion and the bottom of the memory hole MH is likely to increase.

In the embodiment, since fluorine is diffused in the semiconductor film 20 and the memory film 30 from the metal oxide film 51 constituting the core film 50 extending in the stacking direction of the stacked body 100, as compared with the ion implantation method, a variation in the content of fluorine between the memory cell on the upper layer side of the stacked body 100 and the memory cell on the lower layer side of the stacked body 100 is suppressed, and thus, a variation in the characteristics between these memory cells can be suppressed.

Further, according to the embodiment, also the conductive layer 70 contains fluorine. As described above, a tungsten layer as the conductive layer 70 is formed by a CVD method using tungsten fluoride gas, or a molybdenum layer as the conductive layer 70 is formed by a CVD method using molybdenum fluoride gas. Fluorine in the source gas (tungsten fluoride gas or molybdenum fluoride gas) is absorbed in the conductive layer 70.

Therefore, fluorine diffusing from at least either of the metal oxide film 51 and the conductive layer 70 is included at least at the Interface between the metal oxide film 51 and the semiconductor film 20, in the semiconductor film 20, at the interface between the semiconductor film 20 and the tunnel insulating film 31, in the tunnel insulating film 31, at the interface between the tunnel Insulating film 31 and the charge storage film 32, in the charge storage film 32, at the interface between the charge storage film 32 and the block insulating film 34, in the block insulating film 34, at the interface between the block insulating film 34 and the titanium nitride film 60, in the titanium nitride film 60, or at the Interface between the titanium nitride film 60 and the conductive layer 70.

Hereinafter, an effect of fluorine added to the inside of the respective films and the respective Interfaces will be described.

As described above, due to a potential difference between the semiconductor film 20 and the conductive layer 70 at the erasing operation, electrons in the conductive layer 70 tunnel back to the memory film 30, and further pass through the semiconductor film 20 and reach the Interface between the core film 50 (metal oxide film 51) and the semiconductor film on the other side across the center axis of the columnar section CL. This may cause damage (defect) in the interface.

In the embodiment, fluorine added to the interface between the semiconductor film 20 and the core film 50 suppresses the formation of the above-mentioned defect or repairs the defect. Therefore, by adding fluorine to the interface between the semiconductor film 20 and the core film 50, the scattering of a carrier at the defect in a channel in the semiconductor film 20 is decreased, and the mobility is improved.

The semiconductor film 20 is, for example, a polycrystalline silicon film, and a defect is likely to occur at the grain boundary. Fluorine added to the inside of the semiconductor film 20 repairs the defect, so that the scattering of a carrier at the defect in a channel is decreased, and the mobility is improved.

A defect is likely to be formed at Interfaces between the respective films constituting the columnar section CL when depositing the films. The defect at the interface may cause a defect in the film. The defect is likely to be formed also in the film itself with the defect at the interface as a starting point.

Fluorine added to the Interface between the semiconductor film 20 and the tunnel insulating film 31 repairs the defect at the interface between the semiconductor film 20 and the tunnel insulating film 31, so that the scattering of a carrier at the defect in a channel is decreased, and the mobility is improved.

Further, a defect at the interface generates Interface states. When a charge is trapped in the interface states by writing and erasing operations, the threshold may be shifted. In particular, even if the amount of a charge trapped at the Interface between the tunnel insulating film 31 and the semiconductor film 20 is small, the threshold is greatly affected.

Fluorine added to the Interface between the semiconductor film 20 and the tunnel insulating film 31 repairs the Interface states (defect states) at the Interface between the semiconductor film 20 and the tunnel insulating film 31.

The tunnel insulating film 31 receives electric field stress at a device operation such as writing or erasing. This stress may cause a defect in the tunnel Insulating film 31. The defect in the tunnel Insulating film 31 increases a leakage current through the tunnel insulating film 31. The increase in the leakage current may cause erroneous writing in non-selected cells at a reading operation.

Further, if a charge trapped in the defect states in the tunnel Insulating film 31 unintendedly tunnels into the semiconductor film 20, the threshold may be shifted from when wiring is performed.

Further, when writing and erasing are performed repeatedly, a charge partially left in the tunnel Insulating film 31 is likely to be present therein. This charge left in the tunnel Insulating film 31 may cause a variation in threshold. Further, a charge in the tunnel Insulating film 31 increases the writing and erasing voltage, and excessive stress is applied to the tunnel Insulating film 31, and thus, defect formation may be accelerated.

Fluorine added to the tunnel Insulating film 31 repairs a defect in the tunnel Insulating film 31 and also the states due to the defect, and thus suppress the above-mentioned problems. The tunnel Insulating film 31 of high quality with few defects can be made thin. By making the tunnel insulating film 31 thin, the device operation voltage such as the writing and erasing voltage can be reduced, and thus, a memory cell with low power consumption can be realized.

When a charge stored in the charge storage film 32 has a deep level, the charge is less likely to be transferred to the tunnel insulating film 31 or the adjacent memory cell.

The defect level of the interface between the charge storage film 32 and the tunnel Insulating film 31 is shallow, and a charge held there may leak into the tunnel insulating film 31 or the adjacent memory cell.

Fluorine added to the interface between the charge storage film 32 and the tunnel Insulating film 31 repairs a defect at the Interface and also the states due to the defect.

As a result, a charge held at a shallow level in the interface between the charge storage film 32 and the tunnel Insulating film 31 can be reduced, and thus, an unintended transfer of the charge can be suppressed.

When fluorine is added to the charge storage film 32, impurity levels are formed, and a charge amount stored in the charge storage film 32 in writing and erasing operations is increased, and the writing and erasing characteristics can be expected to be improved.

The defect level of the Interface between the charge storage film 32 and the block insulating film 34 is shallow, and a charge held there may leak into the block insulating film 34 or the adjacent memory cell.

Fluorine added to the interface between the charge storage film 32 and the block insulating film 34 repairs a defect at the interface and also the states due to the defect. As a result, a charge held at a shallow level in the interface between the charge storage film 32 and the block insulating film 34 can be reduced, and thus, an unintended transfer of the charge can be suppressed.

The block insulating film 34 receives electric field stress at a device operation such as writing and erasing. This stress may cause a defect in the block insulating film 34. The defect in the block insulating film 34 increases a leakage current.

Further, when a charge trapped in the defect states in the block insulating film 34 unintendedly tunnels into the conductive layer 70, the threshold may be shifted from when wiring is performed.

Further, when writing and erasing are performed repeatedly, a charge partially left in the block insulating film 34 is likely to be present therein. This charge left in the block insulating film 34 causes a variation in threshold. Further, a charge in the block insulating film 34 increases the writing and erasing voltage, and excessive stress is applied to the block insulating film 34, and thus, defect formation may be accelerated.

Fluorine added to the block insulating film 34 repairs a defect in the block insulating film 34 and also the states due to the defect, and thus suppress the above-mentioned problems. The block insulating film 34 of high quality with few defects can be made thin. By making the block Insulating film 34 thin, the device operation voltage such as the writing and erasing voltage can be reduced, and thus, a memory cell with low power consumption can be realized.

Due to a large potential difference between the semiconductor film 20 and the conductive layer 70 at an erasing operation, large stress is applied to the block insulating film 34. This stress may cause a defect in the block insulating film 34 with the defect level at the interface between the block insulating film 34 and the conductive layer including the titanium nitride film 60 and the conductive layer 70, as a starting point. This defect in the block Insulating film 34 increases a leakage current between the conductive layer 70 and the charge storage film 32, resulting in supplying electrons to the charge storage film 32 from the conductive layer 70 at an erasing operation. This results in performing a writing operation although the operation mode is an erasing operation mode.

Fluorine added to the interface between the block insulating film 34 and the conductive layer (the titanium nitride film 60 or the conductive layer 70) repairs a defect at the interface and also the states due to the defect. As a result, the occurrence of a defect in the block insulating film 34 is suppressed, and thus, a leakage current through the block insulating film 34 and erroneous writing caused by the leakage current can be suppressed.

As the metal oxide film 51 of the core films 50 and 53, other than an aluminum oxide film (AlOx), a lanthanum oxide film (LaOx), a lanthanum aluminum oxide film (LaAlOx), a hafnium oxide film (HfOx), a hafnium aluminum oxide film (HfAlOx), a hafnium lanthanum oxide film (HfLaOx), a zirconium oxide film (ZrOx), a zirconium hafnium oxide film (ZrHfOx), a zirconium aluminum oxide film (ZrAlOx), a yttrium oxide film (YOx), or a gadolinium oxide film (GdOx) can be used. These oxide films easily absorb fluorine as compared with a silicon oxide film, and also easily desorb fluorine during crystallization in a heat treatment. Further, the metal oxide film 51 may be a stacked film of two or more films selected from the above-mentioned films.

The conductive layer 70 is not limited to a metal layer, and may be a polycrystalline silicon layer to which an impurity (for example, boron) is added at a high concentration, or a metal silicide layer. In such a case, for example, fluorine can be incorporated into the conductive layer (silicon layer) 70 using a gas containing fluorine as an Si source gas when forming the silicon layer by a CVD method, and by a heat treatment thereafter, fluorine can be supplied to the stacked film including the memory film 30 and the semiconductor film 20 from the conductive layer 70.

The thickness of the titanium nitride film 60 to be Interposed between the conductive layer 70 and the block insulating film 34 is desirably 5 nm or less so that the diffusion of fluorine toward the memory film 30 from the conductive layer 70 is not Inhibited.

Further, in addition to the supply of fluorine from the core films 50 and 53 or the conductive layer 70 to the above-mentioned stacked film, by using a gas containing fluorine when depositing the tunnel insulating film 31, the charge storage film 32, and the block insulating film 34, fluorine may be added to the inside of the respective films and the interfaces between the respective films.

Further, by using a film containing fluorine (for example, an aluminum oxide film containing fluorine) as the cover insulating film 33 functioning as a protective film when etching the sacrifice layer 41, fluorine can also be supplied to the charge storage film 32, the tunnel insulating film 31, the semiconductor film 20, and the Interfaces between the respective films from the cover insulating film 33.

While certain embodiments have been described, these embodiments have been presented by way of example only, and are not Intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are Intended to cover such forms or modification as would fall within the scope and spirit of the inventions.

1. A semiconductor device, comprising:
a stacked body including a plurality of conductive layers stacked with an insulating layer between the conductive layers;
a core film extending in the stacked body in a stacking direction of the stacked body, and including a metal oxide film having a higher dielectric constant than a dielectric constant of silicon nitride;
a semiconductor film provided between the conductive layers and the core film, the semiconductor film extending in the stacking direction, the semiconductor film containing fluorine; and
a charge storage portion provided between the semiconductor film and one of the conductive layers.

2. The device according to claim 1, wherein the metal oxide film includes at least one film selected from an aluminum oxide film, a lanthanum oxide film, a lanthanum aluminum oxide film, a hafnium oxide film, a hafnium aluminum oxide film, a hafnium lanthanum oxide film, a zirconium oxide film, a zirconium hafnium oxide film, a zirconium aluminum oxide film, a yttrium oxide film, and a gadolinium oxide film.

3. The device according to claim 1, wherein the semiconductor film is provided in a pipe shape extending in the stacking direction.

4. The device according to claim 3, wherein the metal oxide film is provided in a pillar shape inside the semiconductor film.

5. The device according to claim 3, wherein the metal oxide film is provided in a pipe shape inside the semiconductor film.

6. The device according to claim 5, wherein the core film further has a silicon oxide film provided inside the metal oxide film.

7. (canceled)

8. The device according to claim 1, wherein fluorine is contained at an interface between the core film and the semiconductor film.

9. The device according to claim 1, wherein fluorine is contained in the metal oxide film.

10. The device according to claim 1, wherein fluorine is contained in the conductive layers.

11. The device according to claim 1, further comprising:
a first insulating film provided between the semiconductor film and the charge storage portion, and
a second insulating film provided between the charge storage portion and the one of the conductive layers.

12. The device according to claim 11, wherein fluorine is contained at an interface between the conductive layers and the second insulating film.

13. The device according to claim 11, wherein the second insulating film is also provided between the conductive layers and the insulating layer.

14. The device according to claim 11, further comprising a nitride film provided between the one of the conductive layers and the second insulating film.

15. The device according to claim 1, wherein the conductive layers are metal layers containing at least either of tungsten and molybdenum.

16. A method for manufacturing a semiconductor device, comprising:
forming a stacked body in which a plurality of first layers and a plurality of second layers of a different material from a material of the first layers are alternately stacked;
forming a hole extending in the stacked body in a stacking direction of the stacked body;
forming a semiconductor film
and a metal oxide film in the hole, the metal oxide film having a higher dielectric constant than a dielectric constant of silicon nitride; and
diffusing fluorine absorbed in the metal oxide film toward the semiconductor film by a heat treatment, the fluorine being absorbed in the metal oxide film at least either during or after deposition of the metal oxide film.

17. The method according to claim 16, further comprising:
removing the second layers by etching the second layers through a slit extending in the stacking direction of the stacked body, and forming an air gap between the first layers; and
forming a conductive layer in the air gap.

18. The method according to claim 17, wherein
the conductive layer contains fluorine, and
the fluorine contained in the conductive layer diffuses toward the semiconductor film during the heat treatment.

19. The method according to claim 18, wherein a tungsten layer as the conductive layer is formed by a CVD method using a gas containing tungsten fluoride.

20. The method according to claim 18, wherein a molybdenum layer as the conductive layer is formed by a CVD method using a gas containing molybdenum fluoride.
